(19) United States
(12) Patent Application Publication
(10) Pub. No.: US 2019/0300183 A1
(43) Pub. Date: Oct. 3, 2019

(54) DETECTION OF ICY CONDITIONS FOR AN AIRCRAFT THROUGH ANALYSIS OF ELECTRIC CURRENT CONSUMPTION

(71) Applicant: Airbus Operations (S.A.S.), Toulouse (FR)

(72) Inventors: Thierry Clavel, Montauban (FR); Alice Calmels, Blagnac (FR)

(21) Appl. No.: 16/363,281

(22) Filed: Mar. 25, 2019

(30) Foreign Application Priority Data
Mar. 30, 2018 (FR) 1852810

(51) Int. Cl. B64D 15/22; G01R 1/073; G01R 19/00

(52) U.S. Cl. CPC B64D 15/22; G01R 19/0092; G01R 1/073

(57) ABSTRACT

Method and system for detecting icy conditions for an aircraft, the aircraft including probes installed on its skin and a computer configured so as to acquire measurements of electric currents flowing through the probes in order to manage their electricity consumption. The computer furthermore is configured so as to compare the electric currents flowing through at least two probes and so as to deduce icy conditions from the comparison.

### CROSS-REFERENCE TO RELATED APPLICATION

This application claims priority to French patent application number 18 52810 filed on Mar. 30, 2018, the entire disclosure of which is incorporated by reference herein.

### TECHNICAL FIELD

The disclosure herein generally relates to the estimation of the weather conditions in which an aircraft is situated, and more particularly to the detection of icy conditions.

### BACKGROUND

The occurrence of icy conditions during flight may impact aircraft performance. Thus, when aircraft are certified to fly in icy conditions, they are equipped with protective systems integrated into the elements to be protected (wing, engine air intakes, Pitot probes, etc.). The protective systems take the form in particular of heating systems that prevent the formation or the build-up of ice.

The activation of at least some of these protective systems is generally based on the pilot's judgement after he has identified the presence of icy conditions. Mechanical and/or optical detection systems are generally used to assist the pilot in his judgement. It will be noted that some elements, such as Pitot probe-type sensors, are continuously protected by heating systems, and therefore no action from the pilot is required to protect them from icy conditions. By contrast, other elements such as the wings and engine air intakes require a one-off action from the pilot in order to protect them following detection of icy conditions by the detection system.

It is thus common to equip an aircraft with sensors dedicated to detecting icy conditions, these being mounted on the skin of the aircraft, and to use the measurements that are obtained to diagnose the presence of ice. It remains necessary for the pilot to assess the measurements, taking into account the flight phase, the criticality of the functions performed by the elements impacted by ice and associated safety margins, in order to avoid any unwanted triggering of the protective systems.

These specific detection sensors are installed on the skin of the fuselage or a surface of the aircraft, which firstly requires piercing the fuselage or the surface in question, providing mechanical reinforcements close to the hole, using an electrical wiring system and installing additional acquisition systems in electrical enclosures, increasing weight and costs. Furthermore, the specific sensors often protrude beyond the skin of the fuselage and therefore create drag, which may impact the performance of the aircraft.

Current specific detection sensors perform their function of overall detection of icy conditions well but are not suitable for providing a more accurate diagnosis. Specifically, these specific sensors are not suitable for identifying the formation of large drops of water or ice crystals.

### SUMMARY

One aim of the disclosure herein is to propose a system for detecting icy conditions for an aircraft, which rectifies at least some of the above drawbacks, in particular which does not require additional piercing and wiring operations, does not increase the weight of the plane or its aerodynamic drag, and makes it possible both to perceive a wide range of icy conditions and to provide a more accurate diagnosis than in the prior art.

The disclosure herein relates to a system for detecting icy conditions for an aircraft, the aircraft comprising probes installed on its skin and a computer configured so as to acquire measurements of electric currents flowing through the probes in order to manage their electricity consumption, the computer furthermore being configured so as to compare the electric currents flowing through at least two probes and so as to deduce icy conditions from the comparison.

Thus, comparing the intensities of electric currents, which are already available, of the probes makes it possible to detect the presence of clouds, icy conditions and the water concentration of the clouds. It is no longer necessary to install specific ice detectors, thus making it possible to reduce weight, costs, maintenance and electricity consumption.

Advantageously, the computer is configured so as to compute the ratio of currents between first and second current intensities flowing respectively through first and second probes installed at various locations of the aircraft, the ratio being indicative of icy conditions.

Thus, simply computing a ratio of currents which have already been measured surprisingly makes it possible to have a very reliable indication of icy conditions.

Advantageously, the computer is configured so as to determine a parameter indicative of icy conditions by dividing the ratio of currents by the ratio between first and second water collection coefficients in relation respectively to the first and second probes, and by a cloudless constant.

The icy conditions parameter makes it possible to indicate the presence and the type of icy conditions by discriminating between liquid and solid particles.

Advantageously, the water collection coefficients are predetermined by an aerodynamic code on the basis of the flight conditions, of the location of the probes and of the atmospheric conditions, the values of the collection coefficients being entered in look-up tables that are stored in a storage unit.

Advantageously, the cloudless constant is predetermined by measuring the ratio of currents in relation to the first and second probes in atmospheric conditions with dry air.

According to one embodiment of the disclosure herein, the computer is furthermore configured so as to deduce icy conditions by using learning data that are recorded beforehand. This makes it possible to broaden the detection spectrum and to refine the interpretation of icy conditions.

Advantageously, the computer is configured so as to monitor the evolution of the parameter indicative of icy conditions over time during various flights of the aircraft. This makes it possible to monitor the evolution of icy conditions and of the water concentration of clouds.

Advantageously, the icy conditions data are indicated in real time on an interface in the cockpit of the aircraft.

These data thus make it possible to assist the pilot in his judgement regarding the activation of the protective systems.

Advantageously, the computer is configured so as to compare in pairs the electric currents flowing through a plurality of probes installed at various locations of the aircraft.

This makes it possible to probe the water concentration of clouds.

Advantageously, the icy conditions data determined by the computer are transmitted to a ground weather station by the aircraft.

The ground station is thus able to collect weather data from a plurality of sources at altitude.

The disclosure herein also targets an aircraft having the system for detecting icy conditions according to any one of the preceding features.

The disclosure herein also targets a method for detecting icy conditions for an aircraft, the aircraft comprising probes installed on its skin and a computer configured so as to acquire measurements of electric currents flowing through the probes in order to manage their electricity consumption, the method including comparing the electric currents flowing through at least two probes and deducing icy conditions from the comparison.

### BRIEF DESCRIPTION OF THE DRAWINGS

Other features and advantages of the disclosure herein will become apparent upon reading one preferred embodiment of the disclosure herein, given with reference to the appended, example figures, in which:

FIG. 1 schematically shows an aircraft having a system for detecting icy conditions, according to one embodiment of the disclosure herein;

FIG. 2 schematically illustrates a system for detecting icy conditions, according to one preferred embodiment of the disclosure herein;

FIG. 3 illustrates curves of water collection coefficients as a function of the distance from the skin of the aircraft and in various flight conditions of the aircraft, according to the disclosure herein;

FIG. 4 is a graph illustrating the parameter indicative of icy conditions, according to one embodiment of the disclosure herein; and

FIG. 5 schematically shows a method for detecting icy conditions according to one embodiment of the disclosure herein.

### DETAILED DESCRIPTION

A concept underlying the disclosure herein is that of using current intensity measurements which are already available, without developing and installing specific external sensors, and therefore without implanting devices on the skin of the aircraft in order to detect the presence of icy conditions. Specific sensors are understood in this case to be sensors whose measurements are intended exclusively to detect the presence of ice (for example an ice crystal detector).

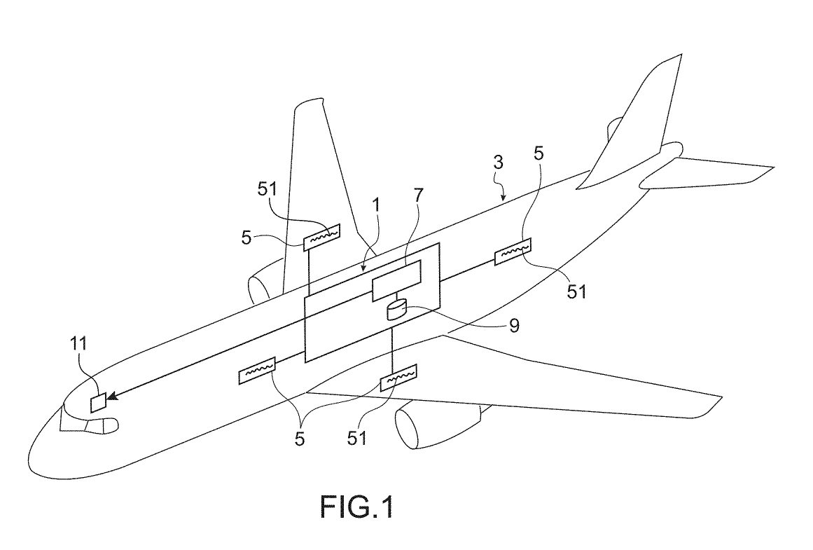

FIG. 1 schematically shows an aircraft having a system 1 for detecting icy conditions, according to one embodiment of the disclosure herein.

Generally speaking, an aircraft 3 has various types of probes 5 for monitoring flight conditions. Specifically, fluid velocity measurement probes of Pitot type, angle of incidence measurement probes, temperature measurement probes, pressure probes, etc. are generally installed on the skin of the aircraft 3. Furthermore, heating elements, and more particularly electric heating circuits 51, are integrated into these probes in order to protect them from icy conditions. An electricity generation system (not illustrated) of the aircraft 3 continuously supplies an electric voltage to the various electric heating circuits 51 integrated into the various probes 5. Moreover, a monitoring system of the aircraft, having a computer 7, is configured so as to acquire measurements of electric currents flowing through the various probes 5 (more precisely the heating circuits 51) in order to manage their electricity consumption and to check that their electric heating circuits 51 are operating correctly. The electric current flowing through a probe 5 depends on the physical characteristics of the probe and on the flight conditions and atmospheric conditions.

According to the disclosure herein, the computer 7 is furthermore configured so as to compare the electric currents simultaneously flowing through at least two probes 5 that are installed on the aircraft. From this comparison, the computer 7 is configured so as to deduce icy conditions.

The electricity consumption of the probes 5 depends on the heat dissipation, into the atmosphere, arising from the electric heating circuits 51. This heat dissipation is correlated with the atmospheric conditions (temperature, pressure, water concentration in clouds, etc.) and with the air flow around the probe. The heat dissipation is thus furthermore linked with the location of the probes 5 on the fuselage. By analysing the differences between the electric currents of the various probes 5, the computer 7 is configured so as to deduce icy conditions.

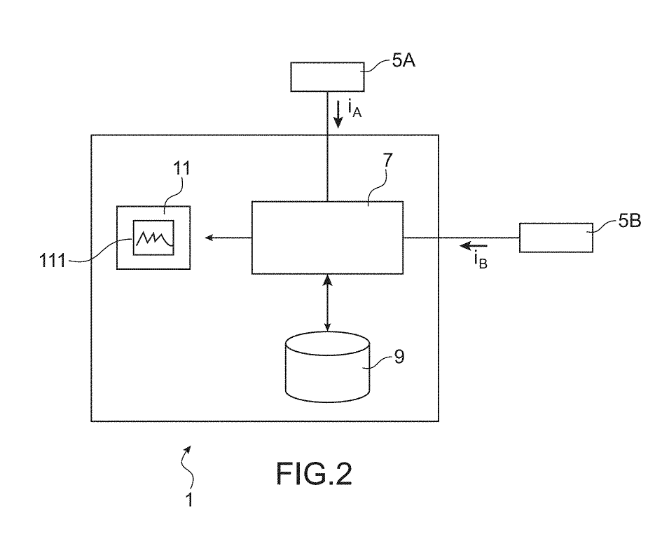

FIG. 2 schematically illustrates a system for detecting icy conditions, according to one preferred embodiment of the disclosure herein.

According to this embodiment, the computer 7 is configured so as to acquire first and second current intensities i_{A} and i_{B} respectively flowing through first 5A and second 5B probes installed at various locations of the aircraft. Furthermore, the computer 7 is configured so as to compute the ratio of currents between the first i_{A} and second i_{B} current intensities.

It has been established that, in a cloudless sky (i.e. without ice), the ratio of currents in relation to two given probes is always equal to a constant C (called cloudless constant C hereinafter) for given flight conditions (altitude, temperature, incidence, Mach number):

$$\frac{{i}_{A}}{{i}_{B}} = C$$

This already gives a first indication in that, if this ratio is not equal to the cloudless constant C, the computer 7 is able to deduce directly that the aircraft is situated in a cloudy zone.

More generally, in any atmospheric environment, and taking into account the fact that the probes 5 may be subject to various local air flows and various local water concentrations, the ratio of the current intensities in relation to the first 5A and second 5B probes may be expressed as follows:

$$\frac{{i}_{A}}{{i}_{B}} = \frac{{β}_{A}}{{β}_{B}} \cdot k \cdot C$$

where C is the cloudless constant for the given flight conditions, k is a parameter indicative of icy conditions, and the ratio

$$\frac{{β}_{A}}{{β}_{B}}$$

is the ratio between first and second water collection coefficients in relation respectively to the first 5A and second 5B probes.

The water collection coefficients β_{A} and β_{B} are predetermined by an aerodynamic code on the basis of the flight conditions, of the location of the probes 5A, 5B and of the type of icy atmospheric conditions (liquid water or crystals). These coefficients are already computed in the context of certifying the aircraft, and their values are entered in look-up tables that are constructed beforehand following the aerodynamic computations. These look-up tables are recorded in a storage unit 9 associated with the computer 7.

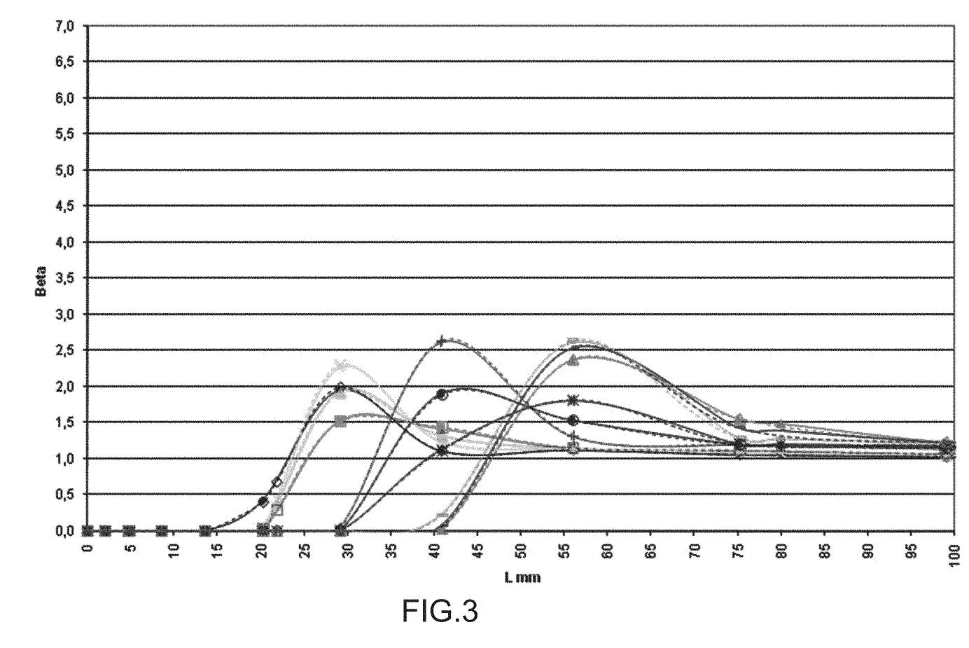

FIG. 3 illustrates, by way of example, curves of water collection coefficients as a function of the distance from the skin of the aircraft and in various flight conditions of the aircraft, according to the disclosure herein.

The curves that are illustrated are created for water droplets having diameters of a few micrometres, and each curve represents a velocity or a given flight condition of the aircraft. It will be noted that the general trend of a curve of coefficient β increases as it moves away from the skin of the aircraft up to a certain value, which depends on the velocity of the aircraft, and then decreases with an asymptomatic tendency towards the value “1”. The curve of a coefficient β gives an accurate indication of the location of a probe and above all of its distance from the skin of the aircraft.

The coefficient β may then advantageously be considered to be an installation parameter of a probe. Moreover, given that the location of each probe 5 on the aircraft 3 is known, the ratio

$$\frac{{β}_{A}}{{β}_{B}}$$

in relation to the first 5A and second 5B probes is therefore easily computed by the computer 7 from the values entered in the look-up tables recorded in the storage unit 9.

Furthermore, the first and second current intensities i_{A} and i_{B} flowing respectively through the first 5A and second 5B probes are already acquired by the computer 7, and their ratio

$$\frac{{i}_{A}}{{i}_{B}}$$

is easily computed thereby.

Likewise, the cloudless constant C is predetermined by simply computing the ratio of currents in relation to the first 5A and second 5B probes in atmospheric conditions with dry air. Advantageously, the value of the cloudless constant C in relation to the corresponding probes is also recorded beforehand in the storage unit 9.

The parameter k indicative of icy conditions is thus determined by the computer 7 by dividing the ratio of currents

$$\frac{{i}_{A}}{{i}_{B}}$$

by the ratio

$$\frac{{β}_{A}}{{β}_{B}}$$

between the first and second water collection coefficients in relation respectively to the first 5A and second 5B probes, and by the cloudless constant C.

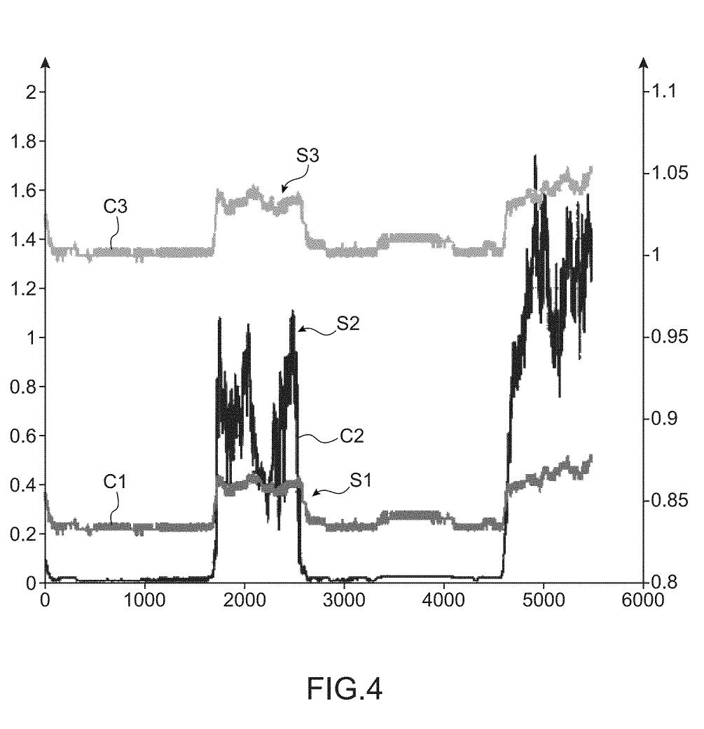

FIG. 4 is a graph illustrating the parameter indicative of icy conditions, according to one embodiment of the disclosure herein.

More particularly, this graph illustrates three parameters as a function of flight time. The first parameter (curve C1) represents the ratio

$$\frac{{i}_{A}}{{i}_{B}}$$

of currents in relation to the current intensities flowing through the first 5A and second 5B probes. The second parameter (curve C2) represents the ratio

$$\frac{{β}_{A}}{{β}_{B}}$$

of the water collection coefficients in relation to the locations of the first 5A and second 5B probes. Finally, the third parameter (curve C3) represents the parameter k indicative of icy conditions determined on the basis of the ratio

$$\frac{{i}_{A}}{{i}_{B}}$$

currents, of the water collection ratio

$$\frac{{β}_{A}}{{β}_{B}}$$

and of the cloudless constant C. It will be noted that the simultaneous jumps S1, S2, S3 illustrated on the curves C1, C2, C3 of the three parameters, respectively, indicate the presence of icy conditions during the flight time in relation to these jumps S1, S2, S3. Additional post-processing may be performed by the computer by more thoroughly comparing the values of the parameter k with the look-up tables recorded in the storage unit 9.

Advantageously, to interpret the icy conditions parameter k with greater accuracy, use is made of a test aircraft (not illustrated) equipped with the detection system 1 according to the disclosure herein and with a specific system comprising test sensors dedicated to directly and accurately detecting water concentration in clouds, ice, and water content (crystals and supercooled water). Specifically, during test flights of the test aircraft, the values of the parameter k are determined by the detection system 1 according to the disclosure herein at the same time as the acquisition of accurate data by the specific system dedicated to direct detection. These accurate data are analysed and correlated with the values of the parameter k so as to form supervised learning data.

Thus, during an operational flight of an aircraft 3, generally of the same type as that used for the test flights, except that this time it does not have specific test sensors, the computer 7 determines the values of the parameter k and compares them with the supervised learning data recorded beforehand in the storage unit 9 so as to perceive a wide range of icy conditions by interpreting the values of the parameter k with greater accuracy.

Furthermore, the computer 7 is configured so as to transmit the icy conditions data to an interface 11 of the cockpit of the aircraft 3 in real time (see FIGS. 1 and 2). These data may thus be displayed on a screen 111 of the cockpit and possibly generate an alarm. The pilot will then have the possibility of activating the systems for protecting against ice. As an alternative, the icy condition may automatically trigger systems for protecting against ice.

Advantageously, the computer 7 is configured so as to monitor the evolution of the parameter indicative of icy conditions over time during the various flights of the aircraft 3 in order to monitor the evolution of the water concentration in clouds.

Moreover, the icy conditions data determined by the computer 7 may be transmitted to a ground weather station by the aircraft 3. The ground station is thus able to analyse these data in greater detail, and advantageously possesses weather data from a plurality of sources at altitude.

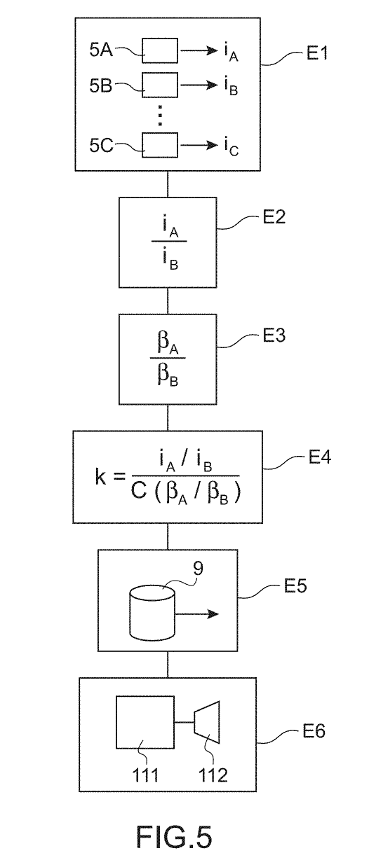

FIG. 5 schematically shows a method for detecting icy conditions according to one embodiment of the disclosure herein.

In step E1, measurements of electric currents flowing through probes 5A-5C installed on the aircraft are collected, for example, at regular intervals of the flight.

In steps E2 through E4, the electric currents i_{A} and i_{B} flowing through at least two probes 5A, 5B installed at various locations of the aircraft are compared, and icy conditions are deduced from this comparison. If the electric current measurements are collected from a plurality of probes, the latter are grouped together in pairs by choosing, in each pair, two probes installed at various locations of the aircraft. For the sake of simplicity, reference is made hereinafter to just two current intensities collected from two probes (first 5A and second 5B probes).

More particularly, in step E2, the ratio of currents

$$\frac{{i}_{A}}{{i}_{B}}$$

between first and second current intensities i_{A} and i_{B} flowing respectively through the first 5A and second 5B probes is computed.

In step E3, the values of the water collection coefficients in relation to the first 5A and second 5B probes are looked up from the look-up tables established beforehand. The acquired values are those that correspond to the locations of the first and second probes and to the current flight conditions. Next, the ratio

$$\frac{{β}_{A}}{{β}_{B}}$$

between first and second water collection coefficients is computed.

In step E4, the parameter k indicative of icy conditions is computed on the basis of the ratio

$$\frac{{β}_{A}}{{β}_{B}}$$

of currents, of the ratio

$$\frac{{i}_{A}}{{i}_{B}}$$

between the first and second water collection coefficients, and of the cloudless constant C recorded beforehand in the storage unit.

In step E5, icy conditions are possibly determined with greater accuracy by taking into account the supervised learning data recorded beforehand.

In step E6, the icy conditions are displayed on a screen 111 of the cockpit, and an alarm 112 is possibly generated when ice is detected. The pilot will then have the opportunity to activate the systems for protecting against ice. As an alternative, the icy condition may automatically trigger systems for protecting against ice.

The subject matter disclosed herein can be implemented in or with software in combination with hardware and/or firmware. For example, the subject matter described herein can be implemented in software executed by a processor or processing unit. In one exemplary implementation, the subject matter described herein can be implemented using a computer readable medium having stored thereon computer executable instructions that when executed by a processor of a computer control the computer to perform steps. Exemplary computer readable mediums suitable for implementing the subject matter described herein include non-transitory devices, such as disk memory devices, chip memory devices, programmable logic devices, and application specific integrated circuits. In addition, a computer readable medium that implements the subject matter described herein can be located on a single device or computing platform or can be distributed across multiple devices or computing platforms.

While at least one exemplary embodiment of the invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a”, “an” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A system for detecting icy conditions for an aircraft, the aircraft comprising probes installed on a skin of the aircraft and a computer configured to acquire measurements of electric currents flowing through the probes to manage electricity consumption by the probes, wherein the computer is configured to compare in a comparison the electric currents flowing through at least two probes and to deduce icy conditions from the comparison.

2. The system according to claim 1, wherein the computer is configured to compute a ratio of currents between first and second current intensities flowing respectively through first and second probes installed at various locations of the aircraft, the ratio being indicative of icy conditions.

3. The system according to claim 2, wherein the computer is configured to determine a parameter indicative of icy conditions by dividing the ratio of currents by a ratio between first and second water collection coefficients in relation respectively to the first and second probes, and by a cloudless constant.

4. The system according to claim 3, wherein the water collection coefficients are predetermined by an aerodynamic code on a basis of flight conditions, of a location of the probes and of atmospheric conditions, values of the collection coefficients being entered in look-up tables that are stored in a storage unit.

5. The system according to claim 3, wherein the cloudless constant is predetermined by measuring the ratio of currents in relation to the first and second probes in atmospheric conditions with dry air.

6. The system according to claim 1, wherein the computer is furthermore configured to deduce icy conditions by using learning data that are recorded beforehand.

7. The system according to claim 1, wherein icy conditions data are indicated in real time on an interface in a cockpit of the aircraft.

8. The system according to claim 1, wherein the computer is configured to compare in pairs electric currents flowing through a plurality of probes installed at various locations of the aircraft.

9. The system according to claim 1, configured for icy conditions data determined by the computer to be transmitted to a ground weather station by the aircraft.

10. An aircraft comprising the system for detecting icy conditions according to claim 1.

11. A method for detecting icy conditions for an aircraft, the aircraft comprising probes installed on a skin of the aircraft and a computer configured to acquire measurements of electric currents flowing through the probes to manage electricity consumption by the probes, the method comprising comparing in a comparison the electric currents flowing through at least two probes and deducing icy conditions from the comparison.
